(19) United States
(12) Patent Application Publication
(10) Pub. No.: US 2020/0152910 A1
(43) Pub. Date: May 14, 2020

(54) DISPLAY DEVICE

(71) Applicant: Sharp Kabushiki Kaisha, Sakai City, Osaka (JP)

(72) Inventors: Tohru OKABE, Sakai City (JP); Shinsuke SAIDA, Sakai City (JP); Hiroki TANIYAMA, Sakai City (JP); Shinji ICHIKAWA, Sakai City (JP); Ryosuke GUNJI, Sakai City (JP); Akira INOUE, Sakai City (JP); Yoshihiro NAKADA, Sakai City (JP); Hiroharu JINMURA, Sakai City (JP)

(21) Appl. No.: 16/473,262

(22) PCT Filed: Sep. 29, 2017
(86) PCT No.: PCT/JP2017/035729

§ 371 Date: Jun. 25, 2019

(51) Int. Cl. H01L 51/52; H01L 27/32; H01L 51/56

(52) U.S. Cl. CPC H01L 51/5253; H01L 51/56; H01L 27/3258; H01L 27/3276

(57) ABSTRACT

The display device includes: a TFT layer; a light-emitting layer in an upper layer than the TFT layer; a first inorganic sealing film in an upper layer than the light-emitting layer; and a second inorganic sealing film in an upper layer than the first inorganic sealing film. An organic edge film is provided on a peripheral edge of a frame region surrounding a display region. The second inorganic sealing film overlaps with an upper face of the organic edge film, and an end face of the organic edge film and an end face of the second inorganic sealing film are aligned with each other.

### TECHNICAL FIELD

The disclosure relates to a display device.

### BACKGROUND ART

When a display device including an EL element is manufactured, a layered body, which is formed on a mother base material and includes a TFT layer, a light-emitting element layer, a sealing layer, and the like, is divided to obtain a plurality of display devices (individual pieces).

### CITATION LIST

### Patent Literature

PTL 1: JP 2010-141181 A (published on Jun. 24, 2010).

### SUMMARY

### Technical Problem

Performance of a display device may deteriorate due to cracking and the like occurring in partitioning portions.

### Solution to Problem

The display device according to one aspect of the disclosure includes: a TFT layer; a light-emitting layer in an upper layer than the TFT layer; a first inorganic sealing film in an upper layer than the light-emitting layer; and a second inorganic sealing film in an upper layer than the first inorganic sealing film. An organic edge film is provided on a peripheral edge of a frame region surrounding a display region. The second inorganic sealing film overlaps with an upper face of the organic edge film, and an end face of the organic edge film and an end face of the second inorganic sealing film are aligned with each other.

### Advantageous Effects of Disclosure

According to one aspect of the disclosure, the occurrence of cracking or the like is suppressed in partitioning portions.

### BRIEF DESCRIPTION OF DRAWINGS

FIG. 1 is a flowchart illustrating an example of a manufacturing method of a display device.

FIGS. 2A and 2B are cross-sectional views illustrating a configuration example of a display portion of the display device.

FIG. 3 is a plan view illustrating a manufacturing method of the display device according to a first embodiment.

FIGS. 4A and 4B are cross-sectional views, each illustrating a manufacturing method of the display device according to the first embodiment.

FIG. 5 is a plan view illustrating a manufacturing method of the display device according to the first embodiment.

FIGS. 6A and 6B are cross-sectional views illustrating another manufacturing method of the display device.

FIG. 7 is a plan view illustrating another manufacturing method of the display device.

FIGS. 8A and 8B are cross-sectional views illustrating another configuration of the display device according to the first embodiment.

FIG. 9 is a block diagram illustrating a configuration of a display device manufacturing apparatus.

FIG. 10 is a plan view illustrating a manufacturing method of a display device according to a second embodiment.

FIGS. 11A and 11B are cross-sectional views of the bending portion in FIG. 7.

FIG. 12 is a cross-sectional view illustrating a bending state of the display device according to the second embodiment.

FIGS. 13A and 13B are cross-sectional views of the partitioning portion in FIG. 7.

### DESCRIPTION OF EMBODIMENTS

Hereinafter, “the same layer” means that the layer is formed in the same process (film formation process), “a lower layer” means that the layer is formed in an earlier process than the process in which the layer to compare is formed, and “an upper layer” means that the layer is formed in a later process than the process in which the layer to compare is formed.

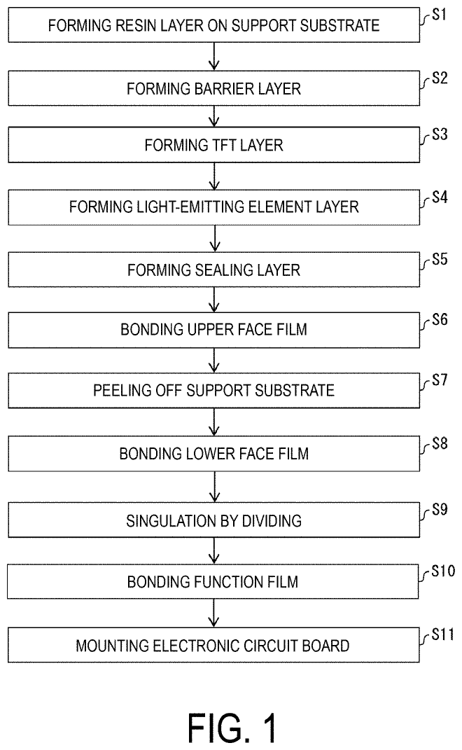

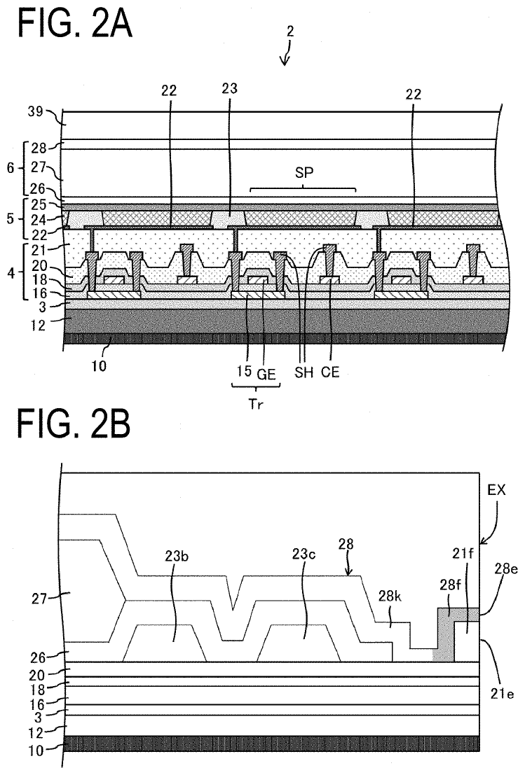

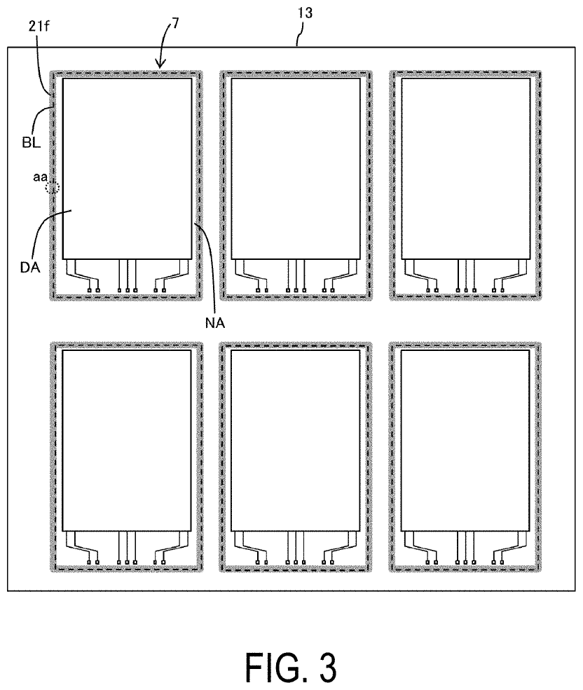

FIG. 1 is a flowchart illustrating an example of a manufacturing method of a display device. FIGS. 2A and 2B are cross-sectional views illustrating a configuration example of a display portion of the display device. FIG. 3 is a plan view illustrating a manufacturing method of the display device.

When a flexible display device is manufactured, as illustrated in FIG. 1 to FIG. 3, a resin layer 12 is first formed on a transparent support substrate 13 (for example, mother glass) (step S1). Next, a barrier layer 3 is formed (step S2). Next, a TFT layer 4 is formed (step S3). Next, a top-emitting light-emitting element layer (for example, OLED element layer) 5 is formed (step S4). Next, a sealing layer 6 is formed (step S5). Next, an upper face film is bonded on the sealing layer 6 (step S6).

Next, the lower face of the resin layer 12 is irradiated with laser light through the support substrate to lower the bonding force between the support substrate 13 and the resin layer 12, and the support substrate 13 is peeled off from the resin layer 12 (step S7). Next, a lower face film 10 is bonded on the lower face of the resin layer 12 (step S8). Next, a layered body 7 including the lower face film 10, the resin layer 12, the barrier layer 3, the TFT layer 4, the light-emitting element layer 5, and the sealing layer 6 is divided by the partition lines BL (see FIG. 3), and a plurality of individual pieces are obtained (step S9). Next, a function film 39 is bonded on the individual pieces obtained (step S10). Next, an electronic circuit board (IC chip, for example) is mounted on the terminal for external connection (step S11). It should be noted that each of the steps is performed by a display device manufacturing apparatus described below.

Examples of a material of the resin layer 12 include polyimide, and examples of a material of the lower face film 10 include polyethylene terephthalate (PET).

The barrier layer 3 is a layer for preventing foreign matters such as water and oxygen from reaching the TFT layer 4 and the light-emitting element layer 5 and, for example, can be formed of a silicon oxide film, a silicon nitride film, or a silicon oxynitride film; or a layered film of these formed by CVD.

The TFT layer 4 includes a semiconductor film 15, an inorganic insulating film 16 (gate insulating film) in an upper layer than the semiconductor film 15; a gate electrode GE in an upper layer than the inorganic insulating film 16; an inorganic insulating film 18 in an upper layer than the gate electrode GE; a capacitance wiring line CE in an upper layer than the inorganic insulating film 18; an inorganic insulating film 20 in an upper layer than the capacitance wiring line CE; a source wiring line SH in an upper layer than the inorganic insulating film 20; and a flattening film 21 (interlayer insulating film) in an upper layer than the source wiring line SH.

In a frame region NA of the TFT layer 4, a terminal used for connection with an electronic circuit board such as an IC chip and an FPC; and a terminal wiring line for connecting the terminal with a wiring line of the display line DA and the like are formed.

The semiconductor film 15 is formed of, for example, low temperature polysilicon (LTPS) or an oxide semiconductor. In FIGS. 2A and 2B, the TFT with the semiconductor film 15 as a channel has a top gate structure but may have a bottom gate structure (for example, when the channel of the TFT is an oxide semiconductor). It should be noted that a thin layer transistor Tr (TFT) is formed to include the semiconductor film 15, the inorganic insulating film 16, and the gate electrode GE.

The gate electrode GE, the capacitance electrode CE, the source wiring line SH, the terminal, and the terminal wiring line are formed of, for example, a monolayer film or a layered film of metal containing at least one of aluminum (Al), tungsten (W), molybdenum (Mo), tantalum (Ta), chromium (Cr), titanium (Ti), or copper (Cu).

The inorganic insulating films 16, 18, and 20 can be formed of, for example, a silicon oxide (SiOx) film or a silicon nitride (SiNx) film; or a layered film thereof formed by a CVD method.

The flattening film 21 can be formed of, for example, a coatable photosensitive organic material such as polyimide or acrylic.

The light-emitting element layer 5 (for example, organic light emitting diode layer) includes an anode 22 in an upper layer than the flattening film 21; an anode edge cover 23, having insulating properties, for covering the edge of the anode 22; an electroluminescence (EL) layer 24 in an upper layer than the anode 22; and a cathode 25 in an upper layer than the EL layer 24 and includes, for each subpixel, a light emitting element (for example, organic light emitting diode (OLED)) including the anode 22 in an island shape, the EL layer 24, and the cathode 25; and a sub pixel circuit for driving the light emitting element. The anode edge cover 23 can be formed of, for example, a coatable photosensitive organic material such as polyimide or acrylic.

The EL layer 24 is formed by layering, for example, a hole injection layer, a hole transport layer, a light-emitting layer, an electron transport layer, and an electron injection layer in this order from the lower layer side. The light-emitting layer is formed in an island shape for each subpixel by using a vapor deposition method or ink-jet method. Other layers are formed in an island shape or a solid-like shape (common layer). In addition, a configuration is also possible in which one or more layers of the hole injection layer, the hole transport layer, the electron transport layer, and the electron injection layer are not formed.

The anode electrode (anode) 22 is formed by layering of indium tin oxide (ITO) and silver (Ag); or indium tin oxide (ITO) and alloy containing Ag, for example, and has light reflectivity (described in detail below). The cathode 25 can be formed of a transparent conductive material such as MgAg alloy (ultra-thin film), indium tin oxide (ITO), and indium zinc oxide (IZO).

When the light-emitting element layer 5 is an OLED layer, a positive hole and an electron are recombined in the EL layer 24 due to the drive current between the anode 22 and the cathode 25, and the resulting exciton falls to the ground state, which causes light to be emitted. Since the cathode 25 is transparent and the anode 22 has light reflectivity, the light emitted from the EL layer 24 travels upward and becomes top-emitting.

The light-emitting element layer 5 may be used not only in a case of constituting the OLED element, but also in a case of constituting an inorganic light emitting diode or a quantum dot light emitting diode.

The sealing layer 6 is transparent and includes an inorganic sealing film 26 for covering the cathode 25, an organic sealing film 27 in an upper layer than the inorganic sealing film 26, and an inorganic sealing film 28 in an upper layer than the organic sealing film 27. The sealing layer 6 for covering the light-emitting element layer 5 prevents foreign matters such as water and oxygen from penetrating into the light-emitting element layer 5.

Each of the inorganic sealing film 26 and the inorganic sealing film 28 can be formed of, for example, a silicon oxide film, a silicon nitride film, or a silicon oxynitride film; or a layered film of these, formed by CVD. The organic sealing film 27 is a transparent organic film having a flattening effect and can be formed of a coatable organic material such as acrylic.

The lower face film 10 is a film, bonded on the lower face of the resin layer 12 after the support substrate is peeled off, for achieving a display device with excellent flexibility, and examples of the material of the lower face film 10 include PET. The function film 39 includes, for example, an optical compensation function, a touch sensor function, a protection function, or the like.

In the above, the case of manufacturing a flexible display device is described, but in the case of manufacturing a non-flexible display device, since the substrate does not need to be replaced, the process transitions from step S5 to step S9 in FIG. 1, for example.

### First Embodiment

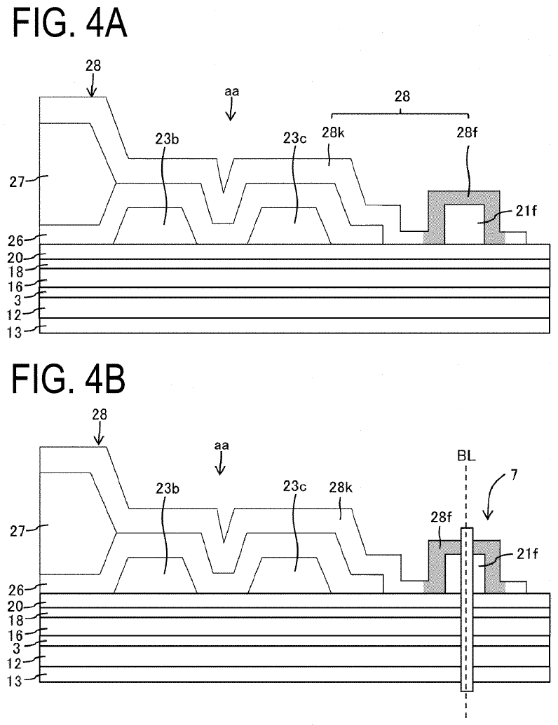

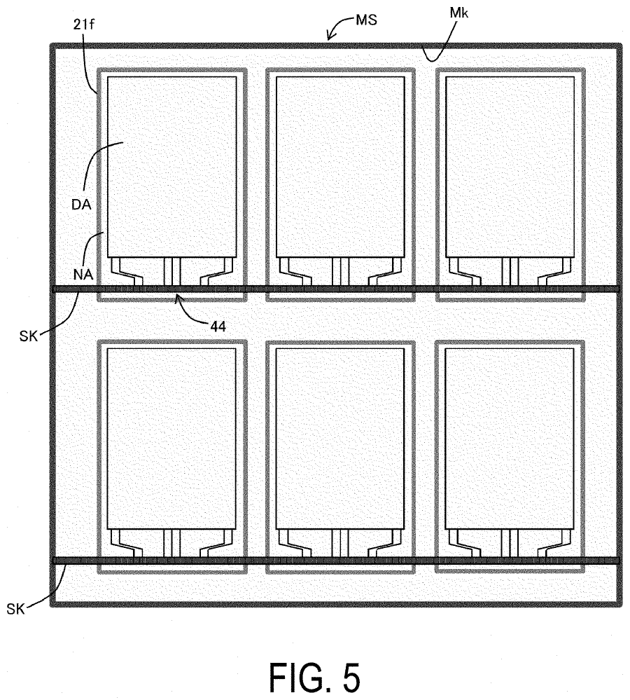

FIGS. 4A and 4B are cross-sectional views illustrating the manufacturing method of the display device according to the first embodiment. FIG. 5 is a plan view illustrating the manufacturing method of the display device according to the first embodiment. As illustrated in FIG. 3 and FIGS. 4A and 4B, in step S4 in FIG. 1, double banks 23b and 23c (protruding structure surrounding a display region DA) are formed in the frame region (non-display region) NA. The banks 23b and 23c are formed in the same layer (in the same process) as the anode edge cover 23 by using, for example, polyimide. The banks 23b and 23c function as liquid stoppers when the organic sealing film 27 is applied by inkjet applying.

In the first embodiment, in step S3 in FIG. 1, an organic edge film 21f in a frame shape is formed, in the frame region NA, in a region outside the banks 23b and 23c in a plan view. The organic edge film 21f is formed in the same layer (in the same process) as the flattening film 21 in FIGS. 2A and 2B by using, for example, acrylic.

In step S5 in FIG. 1, in an upper layer than the light-emitting element layer formed in step S4, the inorganic sealing film 26 (first inorganic sealing film), the organic sealing film 27, and the inorganic sealing film 28 (second inorganic sealing film) are formed in this order. The inorganic sealing film 28 is formed to cover the whole organic sealing film 27, the end portions of the inorganic sealing film 26, and the organic edge film 21f. In the inorganic sealing film 28, a part 28k not overlapping with the organic edge film 21f is a silicon nitride film; and a part 28f overlapping with the organic edge film 21f is a silicon inorganic film containing oxygen. This is because when the film formation process of silicon nitride is performed by using the CVD method using a mask MS as illustrated in FIG. 5, the part 28k not overlapping with the organic edge film 21f is formed as a silicon nitride film, but the part 28f for covering the organic edge film 21f absorbs moisture from the organic edge film 21f (for example, acrylic film) and is formed as a silicon oxide film or a silicon oxynitride (SiON).

As illustrated in FIG. 5, one side of the frame region NA is provided with a terminal portion 44 including a plurality of terminals to which external signals are input, and the inorganic sealing film 28 is formed to cover, with the mask MS, the whole display region DA and the whole part other than the terminal portion 44 of the frame region NA. The mask MS includes an opening Mk common to a plurality of panel regions, and the inorganic sealing film 28 is formed in the region of the opening Mk. It should be noted that the mask MS includes a blocking portion SK at a position corresponding to the terminal portion 44, and the inorganic sealing film 28 is not formed on the terminal portion 44.

The silicon nitride film has a high denseness and excellent sealing performance but is so hard that cracking tends to occur in dividing. On the other hand, the sealing performance of the silicon oxide film is inferior to that of the silicon nitride film, but the silicon oxide film is softer than the silicon nitride film such that the occurrence of cracking is suppressed in dividing. Therefore, in step S9, as illustrated in FIG. 3 and FIG. 4B, dividing the layered body 7 in the thickness direction (for example, laser partition) with a cutting line BL causes the occurrence of cracking to be suppressed in the sealing layer 6 (particularly the inorganic sealing film 28), the cutting line BL overlapping with the end portion 28f of the inorganic sealing film 28 (a part formed of the silicon oxide film overlapping with the organic edge film 21f) and the organic edge film 21f (acrylic film).

In a display device 2 obtained through the dividing in step S9, as illustrated in FIG. 2B, an end face 28e of the inorganic sealing film 28 for covering the upper face of the organic edge film 21f and the end face 21e of the organic edge film are aligned. The alignment of two or more end faces means that these faces are aligned in the same plane (cutting surface). In FIG. 2B, the end face 28e of the inorganic sealing film 28 and the end face 21e of the organic edge film are contiguously flush with each other, and these both end faces (21e and 28e) constitute a part of the edge EX of the display device 2. It should be noted that the end face 28e of the inorganic sealing film 28 and the end face 21e of the organic edge film are also aligned with the end face of the resin layer 12 and the end face of the TFT layer 4.

It should be noted that the organic edge film 21f may be in a forwardly tapered shape that is gradually narrowing upward, and, in a case of a forwardly tapered shape, the taper angle is preferably steep (close to 90 degrees). Thus, even if cracking occurs in the end portion 28f (a part formed of the silicon oxide film) of the inorganic sealing film 28 in dividing, the propagation of cracking into the inner part 28k (a part formed of the silicon nitride film) of the inorganic sealing film 28 is suppressed.

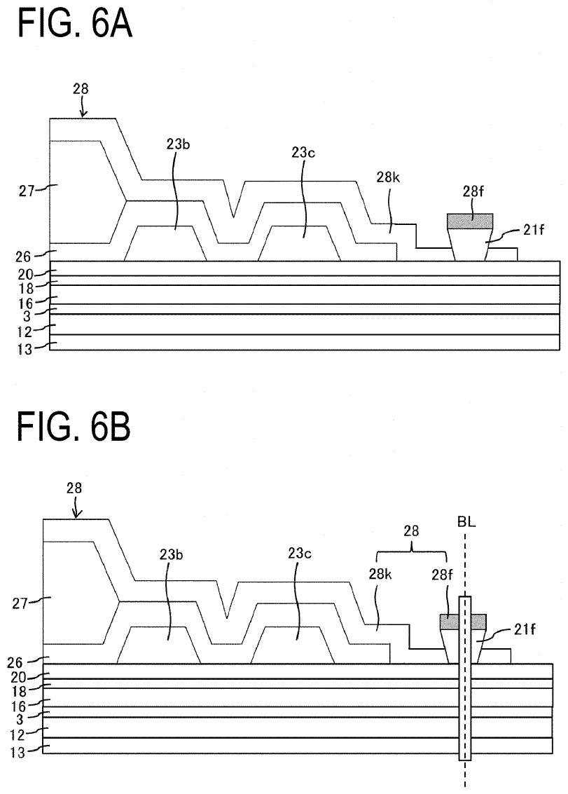

FIGS. 6A and 6B are cross-sectional views illustrating another configuration of the display device according to the first embodiment. As illustrated in FIGS. 6A and 6B, the organic edge film 21f in an inversely tapered shape that is gradually narrowing downward causes the part 28f (silicon oxide film) of the inorganic sealing film 28 to be formed in an island shape on the organic edge film 21f so that, even if cracking occurs in the part 28f (silicon oxide film) of the inorganic sealing film 28 in dividing, the propagation of cracking into the inner part 28k of the inorganic sealing film 28 is suppressed.

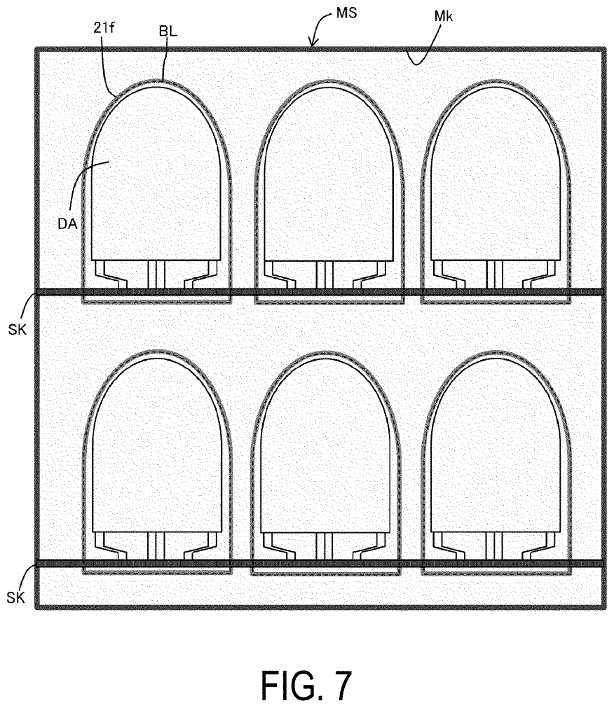

FIG. 7 is a plan view illustrating another manufacturing method of the display device. As illustrated in FIG. 7, even when a deformed panel (display device) in which a part of the edge is curved is formed, the mask MS having the opening Mk common to a plurality of panel regions can be used, the opening Mk being similar to that in FIG. 5. Regarding the deformed panel, it is considered to prepare a mask including a curved blocking portion to prevent cracking in dividing (not to form a silicon nitride sealing film in partitioning portions), but in the first embodiment, if the organic edge film 21f is formed in a curved shape along the curved edge, the part 28f of the inorganic sealing film formed on the organic edge film 21f becomes a flexible silicon oxide film so that the occurrence of cracking is suppressed in dividing.

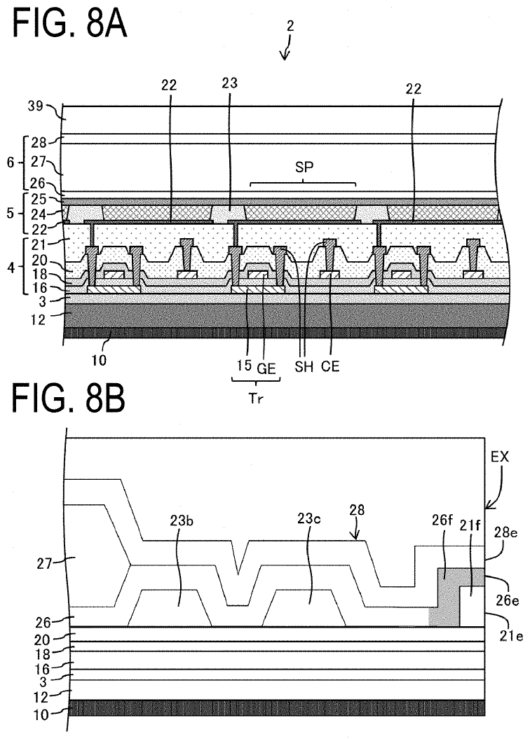

FIGS. 8A and 8B are cross-sectional views illustrating a modified example of the display device according to the first embodiment. In FIGS. 2A and 2B, and FIG. 3, the inorganic sealing film 26 is formed inside the edge of the inorganic sealing film 28, but the disclosure is not limited thereto. As illustrated in FIGS. 8A and 8B, the inorganic sealing film 26 and the inorganic sealing film 28 may have the same pattern.

In this configuration, the end face 28e of the inorganic sealing film 28 and the end face 26e of the inorganic sealing film 26 for covering the upper face of the organic edge film 21f are contiguously flush with each other, and the end face 26e of the inorganic sealing film 26 for covering the upper face of the organic edge film 21f and the end face 21e of the organic edge film are contiguously flush with each other. These end faces (28e, 26e, and 21e) constitute a part of the edge EX of the display device 2. In this case, since the end portion 26f of the inorganic sealing film 26 (a part overlapping with the organic edge film 21f) is a flexible silicon oxide film, the occurrence of cracking in the sealing layer 6 is suppressed in dividing. This modified example has a merit in that identically shaped masks can be used for forming the inorganic sealing film 26 and the inorganic sealing film 28.

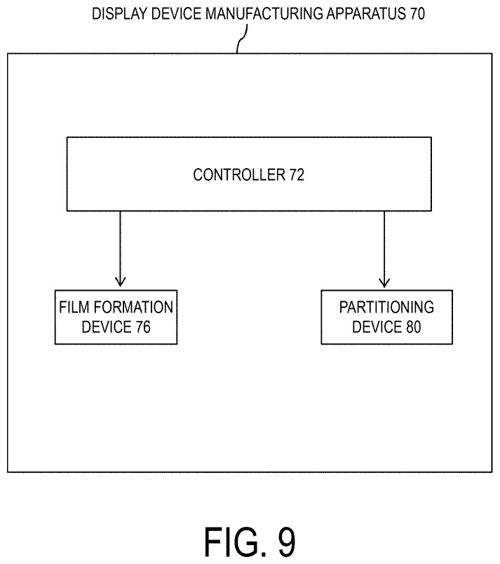

FIG. 9 is a block diagram illustrating a configuration of the display device manufacturing apparatus. As illustrated in FIGS. 6A and 6B, a display device manufacturing apparatus 70 includes a film formation device 76, a partitioning device 80, and a controller 72 for controlling these devices. The film formation device 76 performs steps S1 to S6 in FIG. 1, and the partitioning device 80 performs step S9.

### Second Embodiment

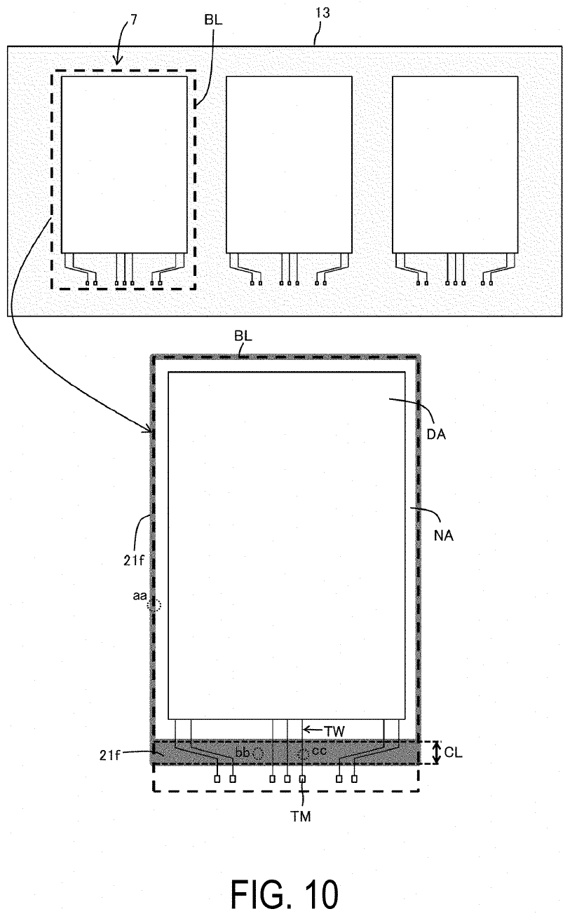

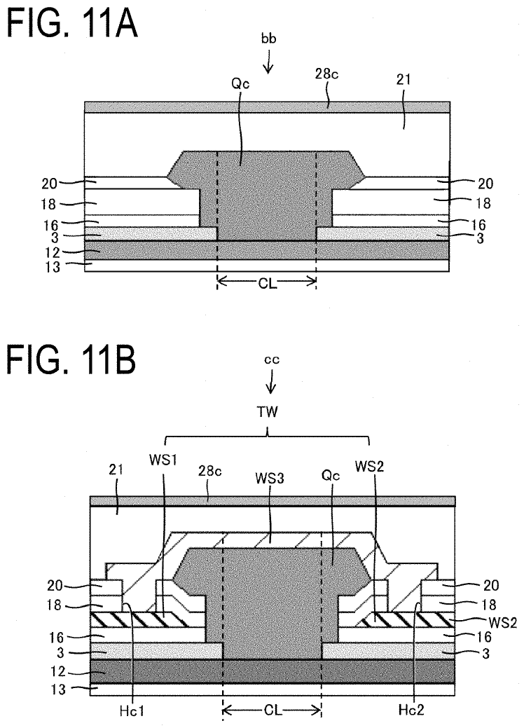

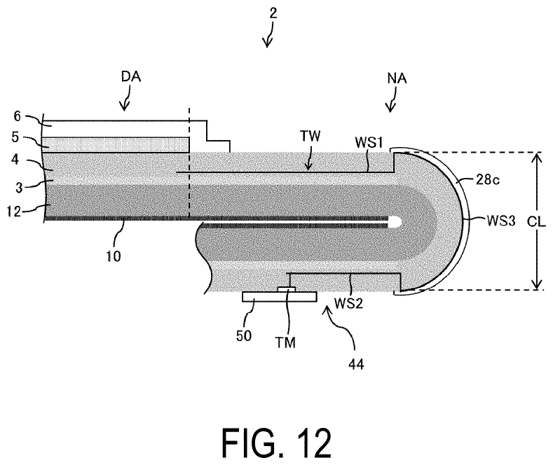

FIG. 10 is a plan view illustrating the manufacturing method of the display device of the second embodiment, FIGS. 11A and 11B are cross-sectional views of the bending portion in FIG. 10, and FIG. 12 is a cross-sectional view illustrating the bending state of the display device of the second embodiment.

As illustrated in FIG. 10 and FIGS. 11A and 11B, the frame region of the layered body 7 (frame region) NA includes the support substrate 13; the resin layer 12; the barrier layer 3; the inorganic insulating films 16, 18, and 20; an organic reinforcing film Qc; a terminal TM; a terminal wiring line TW connected to the terminal TM; the flattening film 21; and a part 28c of the inorganic sealing film 28, and the frame region NA is provided with a bending portion CL.

The terminal TM is connected to the display region DA by the terminal wiring line TW passing through the bending portion CL. The organic reinforcing film Qc is formed of an organic material such as polyimide or acrylic and is formed in an upper layer than the inorganic insulating film 20 and in a lower layer than the terminals TM and TM.

As illustrated in FIGS. 11A and 11B, the barrier layer 3 and the inorganic insulating films 16, 18, and 20 of the bending portion CL each include a penetrated portion to enhance flexibility, and the organic reinforcing film Qc is formed to fill the penetrated portion of the barrier layer 3, the penetrated portion of the inorganic insulating film 16, the penetrated portion of the inorganic insulating film 18, and the penetrated portion of the inorganic insulating film 20.

The terminal wiring lines TW include a wiring line WS1 and a wiring line WS2 positioned on both sides of the bending portion CL and a wiring line WS3, passing through the bending portion CL, that is electrically connected to each of the first wiring line WS1 and the second wiring line WS2. The wiring line WS1 and the wiring line WS2 are formed in the same layer as the gate electrode GE (see FIG. 2A) included in the TFT layer 4. The wiring line WS3 is formed in the same layer as the source wiring line SH included in the TFT layer 4 (see FIG. 2A) and the terminal TM.

The wiring line WS3 extends, over the organic reinforcing film Qc, from one side of the bending portion CL to the other side of the bending portion CL, and is sandwiched between the organic reinforcing film Qc and the flattening film 21 (for example, acrylic film) in the bending portion CL. One end of the wiring line WS3 is connected to the wiring line WS1 through a contact hole Hct extending through the inorganic insulating films 18 and 20, and the other end of the wiring line WS3 is connected to the wiring line WS2 through a contact hole Hc2 extending through the inorganic insulating films 18 and 20. In the bending portion CL, the part 28c of the inorganic sealing film 28 is formed on the flattening film 21.

As illustrated in FIG. 12, the display device 2 is bent by 180 degrees to form the bending portion CL after step S11. This causes the terminal portion 44 on which an electronic circuit board 50 (IC chip or flexible printed circuit board) is mounted to be positioned on the back face, and the frame narrowing is achieved.

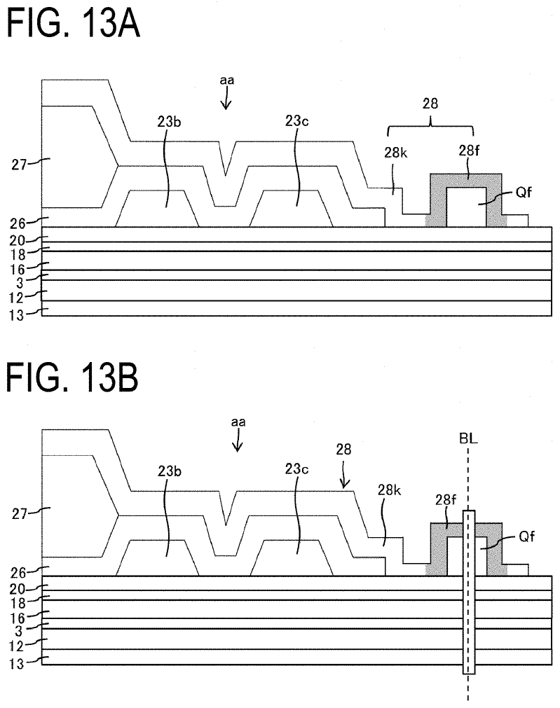

FIGS. 13A and 13B are cross-sectional views illustrating the partitioning portion in FIG. 10. In the second embodiment, in step S3 in FIG. 1, an organic edge film Qf is formed in a region outside the banks 23b and 23c in a plan view. The organic edge film Qf is formed in the same layer (in the same process) as the organic reinforcing film Qc in FIGS. 11A and 11B by using acrylic, for example.

In step S5 in FIG. 1, the inorganic sealing film 26, the organic sealing film 27, and the inorganic sealing film 28 are formed in this order in upper layers than the light-emitting element layer formed in step S4. The inorganic sealing film 28 is formed to cover the whole organic sealing film 27, the end portions of the inorganic sealing film 26, and the organic edge film Qf. The inorganic sealing film 28 has the part 28k, not overlapping with the organic edge film Qf, that is a silicon nitride film; the part 28f, overlapping with the organic edge film Qf, that is a silicon inorganic film containing oxygen; and the part 28c, overlapping with the flattening film 21 in the bending portion CL, that is a silicon inorganic film containing oxygen. This is because, when the film formation process of silicon nitride is performed, by using the CVD method using the mask MS, as illustrated in FIG. 5, the part 28k not overlapping with the organic edge film Qf is formed as a silicon nitride film, but the part 28f for covering the organic edge film Qf absorbs moisture from the organic edge film Qf (for example, acrylic film) and is formed as a silicon oxide film or a silicon oxynitride (SiON). In addition, the part 28c for covering the flattening film 21 in FIG. 12 also absorbs moisture from the flattening film 21 (for example, acrylic film) and is formed as a silicon oxide film or silicon oxynitride (SiON).

Since the silicon oxide film is softer than the silicon nitride film, in step S9, the layered body 7 is divided, as illustrated in FIGS. 10 and 13B, in the thickness direction with the cutting line BL overlapping with the end portion 28f of the inorganic sealing film 28 (a part formed of the silicon oxide film) and the organic edge film Qf (acrylic film) so that the occurrence of cracking is suppressed in the sealing layer 6 (particularly the inorganic sealing film 28). In addition, as illustrated in FIGS. 11B and 12, it is possible to maintain the flexibility of the bending portion CL while protecting the wiring line WS3 with the part 28c (a part formed of the silicon oxide film) of the inorganic sealing film 28.

### Supplement

The electro-optical element (electro-optical element of which luminance and transmittance are controlled by the current) included in the display device according to the present embodiment is not particularly limited. Examples of the display device according to the present embodiment include an organic electro luminescence (EL) display including an organic light emitting diode (OLED) as the electro-optical element, an inorganic EL display including an inorganic light emitting diode as the electro-optical element, and a quantum dot light emitting diode (QLED) display including a QLED as the electro-optical element.

### First Aspect

A display device including:

a TFT layer;

a light-emitting layer in an upper layer than the TFT layer;

a first inorganic sealing film in an upper layer than the light-emitting layer; and

a second inorganic sealing film in an upper layer than the first inorganic sealing film,

wherein an organic edge film is provided on a peripheral edge of a frame region surrounding a display region, and

the second inorganic sealing film overlaps with an upper face of the organic edge film, and an end face of the organic edge film and an end face of the second inorganic sealing film are aligned with each other.

### Second Aspect

The display device according to, for example, the first aspect,

wherein a terminal portion including a plurality of terminals to which external signals are input is provided on an edge of the frame region, and

the second inorganic sealing film is formed in a whole part of the display region and a whole part other than the terminal portion of the frame region.

### Third Aspect

The display device according to, for example, the first or second aspect, wherein the end face of the organic edge film and the end face of the second inorganic sealing film are flush with each other.

### Fourth Aspect

The display device according to, for example, the third aspect, wherein the second inorganic sealing film includes a part overlapping with the organic edge film, the part being a silicon inorganic film containing oxygen, and another part not overlapping with the organic edge film, the other part being a silicon nitride film.

### Fifth Aspect

The display device according to, for example, the first or second aspect, wherein the first inorganic sealing film overlaps with the upper face of the organic edge film, and the end face of the organic edge film and an end face of the first inorganic sealing film are aligned with each other, and formation patterns of the first inorganic sealing film and the second inorganic sealing film are identical.

### Sixth Aspect

The display device according to, for example, the fifth aspect, wherein the end face of the organic edge film, the end face of the first inorganic sealing film, and the end face of the second inorganic sealing film are flush with each other.

### Seventh Aspect

The display device according to, for example, the sixth aspect, wherein the first inorganic sealing film includes a part overlapping with the organic edge film, the part being a silicon inorganic film containing oxygen, and another part not overlapping with the organic edge film, the other part being a silicon nitride film.

### Eighth Aspect

The display device according to any one of, for example, the first to seventh aspects, wherein an edge of the display region includes a curved portion, and the organic edge film is formed along the curved portion.

### Ninth Aspect

The display device according to, for example, the second aspect,

wherein a bending portion is provided on a side of a display region of the terminal portion, and

a terminal wiring line passing through the bending portion is sandwiched between an organic reinforcing film and a flattening film, and the second inorganic sealing film is formed on the flattening film.

Tenth Aspect

The display device according to, for example, the ninth aspect, wherein the second inorganic sealing film has a part overlapping with the flattening film, the part being a silicon inorganic film containing oxygen.

Eleventh Aspect

A method for manufacturing a display device, the method including partitioning a layered body including:

a TFT layer,

a light-emitting layer in an upper layer than the TFT layer,

a first inorganic sealing film in an upper layer than the light-emitting layer, and

a second inorganic sealing film in an upper layer than the first inorganic sealing film, the method including:

forming an organic edge film on a peripheral edge of a frame region surrounding a display region;

forming the second inorganic sealing film overlapping with the organic edge film; and

dividing the layered body with a cutting surface passing through the second inorganic sealing film and the organic edge film.

### Twelfth Aspect

The method for manufacturing a display device according to, for example, the eleventh aspect,

wherein the layered body includes a plurality of panel regions, and

the method further includes forming the second inorganic sealing film by using a mask having an opening common to the plurality of panel regions.

### REFERENCE SIGNS LIST

2 Display device
3 Barrier layer
4 TFT layer
5 Light-emitting element layer
6 Sealing layer
12 Resin layer
16, 18, 20 Inorganic insulating film
21 Flattening film
21f Organic edge film
23 Anode edge cover
23b, 23c Bank
24 EL layer
27 Organic sealing film
28 Inorganic sealing film
70 Display device manufacturing apparatus
Qc Organic reinforcing film
Qf Organic edge film
TM Terminal
TW Terminal wiring line
WS1 to WS3 Wiring line

1: A display device comprising:
a TFT layer;
a light-emitting layer in an upper layer than the TFT layer;
a first inorganic sealing film in an upper layer than the light-emitting layer; and
a second inorganic sealing film in an upper layer than the first inorganic sealing film,
wherein an organic edge film is provided on a peripheral edge of a frame region surrounding a display region,
the second inorganic sealing film overlaps with an upper face of the organic edge film, and
an end face of the organic edge film and an end face of the second inorganic sealing film are aligned with each other,
a terminal portion including a plurality of terminals to which external signals are input is provided on an edge of the frame region,
the second inorganic sealing film is formed in a whole part of the display region and a whole part other than the terminal portion of the frame region,
a bending portion is provided on a side of a display region of the terminal portion, and
a terminal wiring line passing through the bending portion is sandwiched between an organic reinforcing film and a flattening film, and the second inorganic sealing film is formed on the flattening film.

2. (canceled)

3: The display device according to claim 1,
wherein the end face of the organic edge film and the end face of the second inorganic sealing film are flush with each other.

4: The display device according to claim 3,
wherein the second inorganic sealing film includes a part overlapping with the organic edge film, the part being a silicon inorganic film containing oxygen, and another part not overlapping with the organic edge film, the other part being a silicon nitride film.

5: The display device according to claim 1,
wherein the first inorganic sealing film overlaps with the upper face of the organic edge film, and the end face of the organic edge film and an end face of the first inorganic sealing film are aligned with each other, and
formation patterns of the first inorganic sealing film and the second inorganic sealing film are identical.

6: The display device according to claim 5,
wherein the end face of the organic edge film, the end face of the first inorganic sealing film, and the end face of the second inorganic sealing film are flush with each other.

7: The display device according to claim 6,
wherein the first inorganic sealing film includes a part overlapping with the organic edge film, the part being a silicon inorganic film containing oxygen, and another part not overlapping with the organic edge film, the other part being a silicon nitride film.

8: The display device according to claim 1,
wherein an edge of the display region includes a curved portion, and the organic edge film is formed along the curved portion.

9. (canceled)

10: The display device according to claim 19,
wherein the second inorganic sealing film has a part overlapping with the flattening film, the part being a silicon inorganic film containing oxygen.

11-12. (canceled)
